(19) United States
(12) Patent Application Publication
(10) Pub. No.: US 2010/0252875 A1
(43) Pub. Date: Oct. 7, 2010

(54) STRUCTURE AND FABRICATING PROCESS OF NON-VOLATILE MEMORY

(75) Inventor: Riichiro Shirota, Kanagawa (JP)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: POWERCHIP SEMICONDUCTOR CORP., Hsinchu (TW)

(21) Appl. No.: 12/417,639

(22) Filed: Apr. 3, 2009

(51) Int. Cl. H01L 29/788; H01L 21/762; H01L 21/28

(52) U.S. Cl. 257/321; 438/424; 438/594; 257/E29.3; 257/E21.546; 257/E21.209

(57) ABSTRACT

A structure of a non-volatile memory is described, including a substrate, isolation structures disposed in and protrudent over the substrate, floating gates as conductive spacers on the sidewalls of the isolation structures protrudent over the substrate, and a tunneling layer between each floating gate and the substrate. A process for fabricating a non-volatile memory is also described. Isolation structures are formed in a substrate protrudent over the same, a tunneling layer is formed over the substrate, and then floating gates are formed as conductive spacers on the sidewalls of the first isolation structures protrudent over the substrate.

### BACKGROUND OF THE INVENTION

1. Field of Invention

This invention relates to semiconductor device and fabrication, and particularly relates to a floating gate structure, a structure of a non-volatile memory and a process for fabricating a non-volatile memory.

2. Description of Related Art

Non-volatile memory devices are widely applied to various electronic products for data storage, as having small sizes, high operation speed and the ability of retaining data without electric power. Most of current non-volatile devices utilize floating gates for data storage, wherein a floating gate has a rectangular cross section as the process linewidth is 40 nm or larger. However, when the linewidth is reduced to about 30 nm as the limit of current optical lithography or gets even smaller in the future, the cross-sectional shape of the floating gate has to be changed, as explained below.

FIGS. 1A-1C illustrate the evolution of the cross-sectional shape of floating gates in a conventional non-volatile memory as the device linewidth is increasingly reduced.

Referring to FIGS. 1A-1C, to form the memory, a tunneling layer 110 and a poly-Si layer (not shown) are formed on a substrate 100, and the poly-Si layer, the tunneling layer 110 and the substrate 100 are etched using a patterned mask layer (not shown) as a mask to form floating gates 120 and trenches 128. After the trenches 128 are filled by an insulator to form isolation structures 130, an inter-dielectric layer 140 and word lines 150 are formed over the floating gates 120.

In such a non-volatile memory, a word line 150 is required to extend in between the floating gates 120 to make the control gate-floating gate capacitance larger than the floating gate-substrate capacitance and thereby get a sufficient gate coupling ratio (GCR) for normal operations of the memory. Since the thickness of the inter-dielectric layer 140 is usually up to about 12 nm, when the linewidth is reduced close to or smaller than the double of the thickness of the layer 140, the sidewalls of the floating gates 120 have to be tilted to facilitate filling of the inter-dielectric layer 140 in between them. As shown in FIGS. 1B-1C, the smaller the process linewidth is, the larger the tilt angle of the sidewalls of the floating gates 120 is.

However, since the mask layer pattern for defining a floating gate 120 is as wide as the bottom of the floating gate 120, the etching process for forming tilted sidewalls of the same is difficult to control, and the difficulty is greater as the tilt angle is larger.

### SUMMARY OF THE INVENTION

Accordingly, this invention provides a floating gate structure of a non-volatile memory.

This invention also provides a structure of a non-volatile memory that includes the floating gate structure of this invention.

This invention further provides a process for fabricating a non-volatile memory.

The floating gate structure of this invention includes a conductive spacer that is disposed on the sidewall of an isolation structure protrudent over a substrate and is insulated from the substrate.

In an embodiment, the conductive spacer is insulated from the substrate by a tunneling layer.

In an embodiment, the non-volatile memory has a critical dimension smaller than 30 nm.

The structure of a non-volatile memory of this invention includes a substrate, a plurality of first isolation structures disposed in and protrudent over the substrate, a plurality of floating gates as first conductive spacers on sidewalls of the first isolation structures protrudent over the substrate, and a tunneling layer between each floating gate and the substrate.

In an embodiment, the above structure further includes a plurality of second isolation structures lower than the first isolation structures in height, wherein the floating gates are arranged in a row direction and in a column direction, each of the first and the second isolation structures extends in the column direction, the first isolation structures and second isolation structures are arranged alternately in the row direction, and each second isolation structure is located between two columns of floating gates respectively on two opposite sidewalls of two neighboring first isolation structures.

In an embodiment, the above structure further includes a row of select gates as second conductive spacers on the sidewalls of the first isolation structures.

In an embodiment, the non-volatile memory has a critical dimension smaller than 30 nm.

In some embodiments, the floating gates are arranged in a row direction and in a column direction, each of the first isolation structures extends in the column direction, and the above structure further includes a plurality of word lines each disposed over a row of floating gates, and an inter-gate dielectric layer disposed between each floating gate and the word line over the floating gate.

In an embodiment with the inter-gate dielectric layer and word lines, the above structure further includes a plurality of second isolation structures lower than the first isolation structures in height and extending in the column direction, the first isolation structures and second isolation structures are arranged alternately in the row direction, each second isolation structure is located between two columns of floating gates respectively on two opposite sidewalls of two neighboring first isolation structures, and the width of each of the first and second isolation structures is equal to or smaller than double of the thickness of the inter-gate dielectric layer above the floating gates.

In an embodiment with the inter-gate dielectric layer and word lines, the above structure further includes a row of select gates as second conductive spacers on the sidewalls of the first isolation structures protrudent over the substrate, and a select line disposed over and contacting the row of select gates.

The process for fabricating a non-volatile memory of this invention is as follows. A plurality of first isolation structures are formed in a substrate protrudent over the same, a tunneling layer is formed over the substrate, and then a plurality of floating gates are formed as first conductive spacers on sidewalls of the first isolation structures protrudent over the substrate.

In an embodiment, the process further includes forming a plurality of second isolation structures lower than the first isolation structures in height during the step of forming the first isolation structures. The floating gates are arranged in a row direction and in a column direction. Each of the first and second isolation structures extends in the column direction. The first isolation structures and the second isolation structures are arranged alternately in the row direction. Each second isolation structure is located between two columns of floating gates respectively on two opposite sidewalls of two neighboring first isolation structures.

The first and the second isolation structures may be formed with the steps below. A plurality of trenches is formed in the substrate using a patterned mask layer as an etching mask, wherein the mask layer has therein gaps corresponding to the trenches. The trenches and the gaps are filled with a plurality of insulating layers. A part of the insulating layers are recessed in a manner such that the recessed insulating layers and the non-recessed insulating layers are arranged alternately. The mask layer is removed so that the non-recessed insulating layers form the first isolation structures and the recessed insulating layers form the second isolation structures.

In an embodiment, the process further includes forming a row of select gates as second conductive spacers on the sidewalls of the first isolation structures during the step of forming the floating gates.

In an embodiment, the non-volatile memory has a critical dimension smaller than 30 nm.

In an embodiment, the floating gates are formed as follows. A plurality of conductive spacer bars are formed on the sidewalls of the first isolation structures protrudent over the substrate, and then the conductive spacer bars are patterned. In a case where the floating gates are arranged in a row direction and in a column direction and each of the first isolation structures extends in the column direction, the process may further include forming an inter-gate dielectric layer over the substrate after the conductive spacer bars are formed but before the conductive spacer bars are patterned, and forming a plurality of word lines extending in the row direction over the inter-gate dielectric layer, wherein the conductive spacer bars are patterned following the word lines so that each word line is disposed over a row of floating gates.

In an embodiment forming the inter-gate dielectric layer and the word lines, the process further includes, during the step of forming the first isolation structures, forming a plurality of second isolation structures lower than the first isolation structures in height and extending in the column direction. The first isolation structures and the second isolation structures are arranged alternately in the row direction. Each second isolation structure is located between two columns of floating gates respectively on two opposite sidewalls of two neighboring first isolation structures. The width of each of the first and the second isolation structures is equal to or smaller than double of the thickness of the inter-gate dielectric layer above the floating gates.

In an embodiment forming the inter-gate dielectric layer and the word lines, the process further includes the following steps. During the step of patterning the conductive spacer bars, a row of select gates are formed as second conductive spacers on the sidewalls of the first isolation structures protrudent over the substrate. After the step of forming the inter-gate dielectric layer but before the step of forming the word lines, a portion of the inter-gate dielectric layer over portions of the conductive spacer bars predetermined to form the row of select gates is removed such that at least a part of each of the portions of the conductive spacer bars is exposed. During the step of forming the word lines, a select line is formed disposed over and contacting the portions of the conductive spacer bars. In such process, the conductive spacer bars are patterned also following the select line, so that the row of select gates are formed together with the floating gates.

In this invention, since the top surface of a floating gate as a conductive spacer is inclined, the area of its top surface facing the word line is always larger than that of its bottom surface facing the substrate. Therefore, a sufficient GCR can be obtained for normal operation of the memory even when the gap between the sidewalls of two opposite floating gates is filled by the inter-gate dielectric layer. As a result, the width of an isolation structure between two opposite floating gates is allowed to be reduced to double of the thickness of the inter-gate dielectric layer or less, without need to form tapered floating gates as in the conventional non-volatile memory process and hence without difficulty in controlling the etching process of the floating gates.

In order to make the aforementioned and other objects, features and advantages of this invention comprehensible, a preferred embodiment accompanied with figures is described in detail below.

### BRIEF DESCRIPTION OF THE DRAWINGS

FIGS. 1A-1C illustrate the evolution of the cross-sectional shape of floating gates in a conventional non-volatile memory as the device linewidth is increasingly reduced.

FIGS. 2-8 illustrate, in a top view and/or in at least one of two different cross-sectional views, a process for fabricating a non-volatile memory according to an embodiment of this invention, wherein FIG. 8 also illustrates a floating gate structure and a non-volatile memory structure according to the embodiment of this invention.

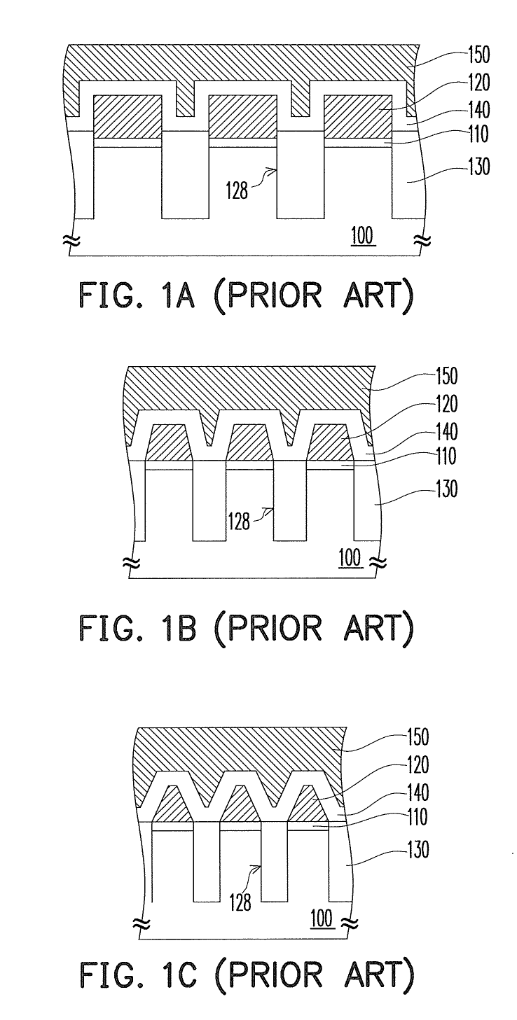

### DESCRIPTION OF EMBODIMENTS

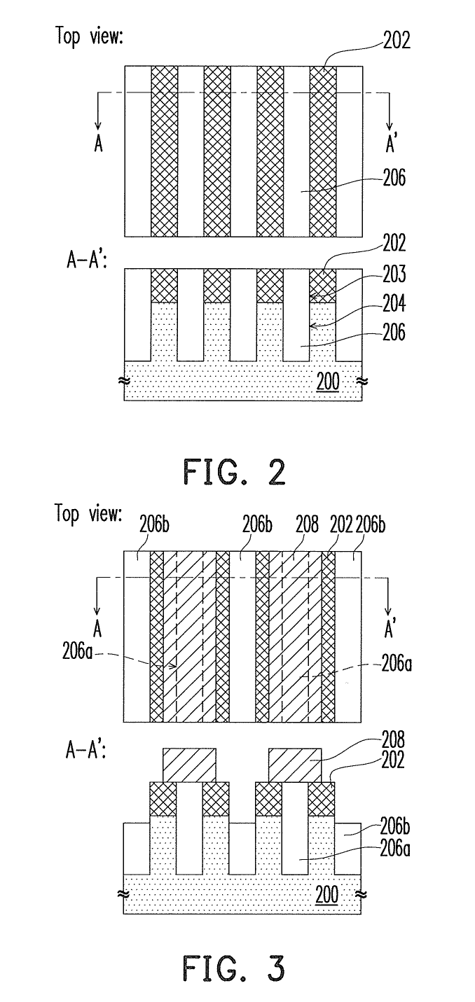

FIGS. 2-8 illustrate, in a top view and/or in at least one of two different cross-sectional views A-A′ and B-B′, a process for fabricating a non-volatile memory according to the embodiment of this invention.

Referring to FIG. 2, a patterned mask layer 202, which has therein gaps 203 for defining isolation trenches, is formed over a semiconductor substrate 200, such as a single-crystal silicon wafer. The substrate 200 is then etched using the mask layer 202 as a mask to form trenches 204 therein, and an insulator, such as silicon dioxide, is filled in the trenches 204 and the gaps 203 to form a plurality of insulating layers 206. The method of forming the insulating layers 206 may include forming a layer of insulator over the substrate 200 filling up the trenches 204 and the gaps 203 and then removing the insulating material outside of the trenches 204 and the gaps 203.

Referring to FIG. 3, a patterned photoresist layer 208 is formed over the substrate 200 covering a part of the insulating layers 206, and then the exposed insulating layers 206b are recessed through etching using the patterned photoresist layer 208 as a mask. The patterned photoresist layer 208 is formed in a manner such that the non-recessed insulating layers 206a and the recessed insulating layers 206b are arranged alternately. Here, the insulating layers 206b are recessed such that no conductive spacer is formed on sidewalls thereof during the later step of forming the floating gates and select gates as conductive spacers on the sidewalls of the non-recessed insulating layers 206a.

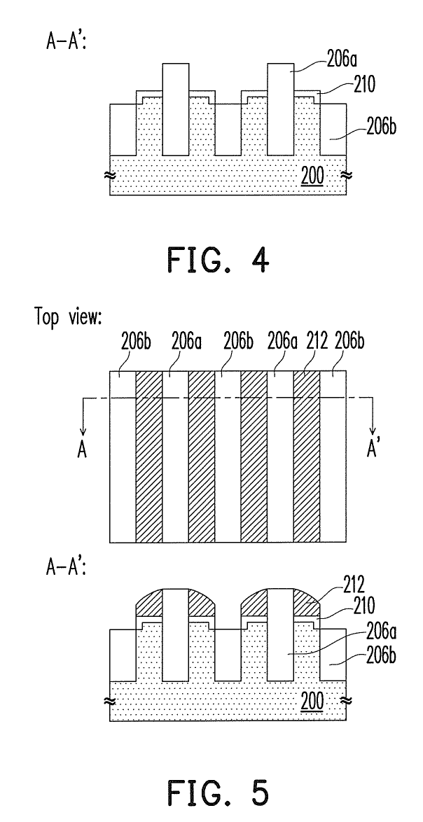

Referring to FIG. 4, the photoresist layer 208 and mask layer 202 are removed so that the non-recessed insulating layers 206a form first isolation structures protrudent over the substrate 200 and the recessed insulating layers 206b form second isolation structures lower then the first isolation structures 206a in height. A tunneling layer 210 is then formed on the exposed surfaces of the substrate 200. The tunneling layer 210 may be an oxide layer, which usually has a thickness of 6-9 nm, preferably about 8 nm, in CV (capacitance vs. voltage) measurement.

Referring to FIG. 5, a plurality of conductive spacer bars 212 are formed on the sidewalls of the first isolation structures 206a. The conductive spacer bars 212 may be formed by depositing a conformal conductive layer (not shown) over the substrate 200 and performing anisotropic etching to remove the portions of the conformal conductive layer over the first and the second isolation structures 206a and 206b.

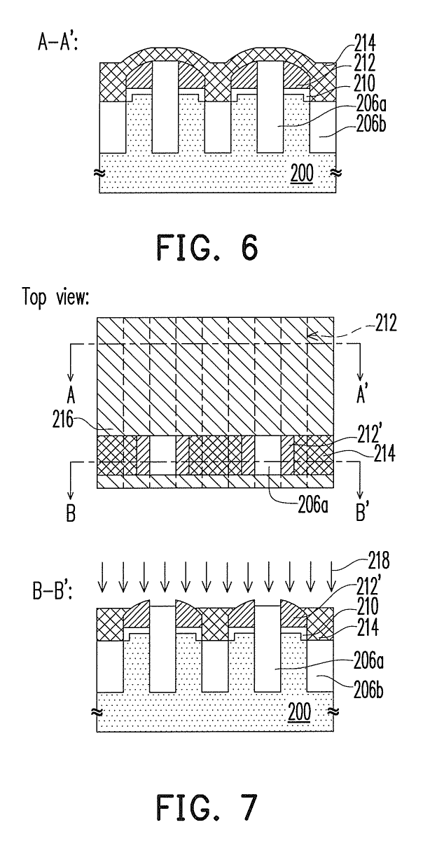

Referring to FIG. 6, an inter-gate dielectric layer 214, such as an ONO composite layer, is formed over the substrate 200 covering the conductive spacer bars 212. When the inter-gate dielectric layer 214 is an ONO composite layer, the thickness thereof is possibly within the range of 9-15 nm, usually about 12 nm, in CV measurement.

Referring to FIG. 7, a patterned photoresist layer 216 is formed over the substrate 200 exposing the inter-gate dielectric layer 214 over the portions 212′ of the conductive spacer bars 212 predetermined to form select gates later. A portion of the inter-gate dielectric layer 214 over the portions 212′ of the conductive spacer bars 212 is then removed, through anisotropic etching 218 using the photoresist layer 216 as a mask, such that at least a part of each portion 212′ is exposed for connection with the select line formed later. The A-A′ cross-sectional view of the resulting structure is the same as FIG. 6.

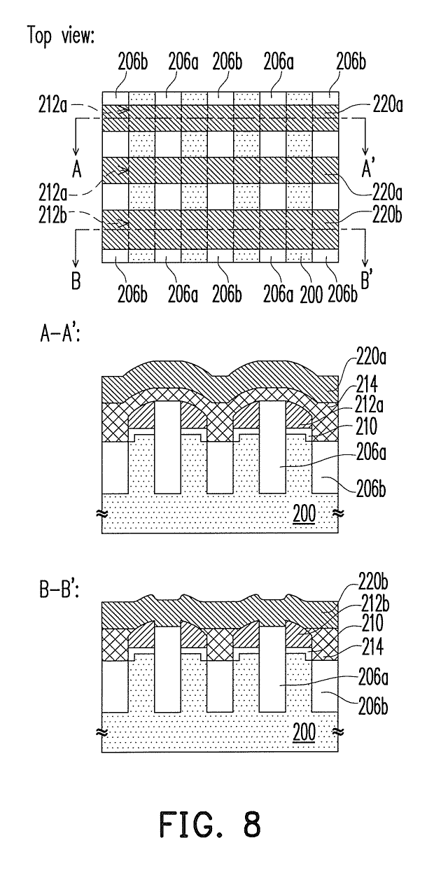

Referring to FIG. 8, the photoresist layer 216 is removed. A plurality of word lines 220a and a select line 220b are formed over the substrate 200 with film deposition, lithography and anisotropic etching as usual, and the anisotropic etching is continued to pattern the conductive spacer bars 212 into a plurality of floating gates 212a and a plurality of the select gates 212b. Each word line 220a is disposed over a row of floating gates 212a and separated from the same by the inter-gate dielectric layer 214, and the select line 220b is disposed over the row of select gates 212b and contacts the same to achieve electrical connection.

After that, for example, buried source lines, separate drain regions and bit lines can be formed by any known process. This will not be illustrated in details as being well known to one of ordinary skill in the art.

Referring to FIG. 8, since the top surface of a floating gate 212a as a conductive spacer is inclined, the area of its top surface facing the word line 220a is always larger than that of its bottom surface facing the substrate 200. Hence, a sufficient GCR can be obtained for normal operation of the memory even when the gap between sidewalls of opposite floating gates 212a is filled by the inter-gate dielectric layer 214. Thus, the width of a second isolation structure 206b between two opposite floating gates 212a, which is usually equal to the width of a first isolation structure 206a protrudent over the substrate 200, is allowed to be reduced to the double of the thickness of the inter-gate dielectric layer 214 or less, without need to form tapered floating gates as in the prior-art non-volatile memory process and hence without difficulty in controlling the etching process of the floating gates.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A floating gate structure in a non-volatile memory, comprising a conductive spacer that is disposed on a sidewall of an isolation structure protrudent over a substrate and is insulated from the substrate.

2. The floating gate structure of claim 1, wherein the conductive spacer is insulated from the substrate by a tunneling layer.

3. The floating gate structure of claim 1, wherein the non-volatile memory has a critical dimension smaller than 30 nm.

4. A structure of a non-volatile memory, comprising:
a substrate;
a plurality of first isolation structures disposed in and protrudent over the substrate;
a plurality of floating gates as first conductive spacers on sidewalls of the first isolation structures protrudent over the substrate; and
a tunneling layer between each floating gate and the substrate.

5. The structure of claim 4, further comprising a plurality of second isolation structures lower than the first isolation structures in height, wherein
the floating gates are arranged in a row direction and in a column direction,
each of the first and second isolation structures extends in the column direction,
the first isolation structures and the second isolation structures are arranged alternately in the row direction, and
each second isolation structure is located between two columns of floating gates respectively on two opposite sidewalls of two neighboring first isolation structures.

6. The structure of claim 4, further comprising a row of select gates as second conductive spacers on the sidewalls of the first isolation structures.

7. The structure of claim 4, wherein the non-volatile memory has a critical dimension smaller than 30 nm.

8. The structure of claim 4, wherein the floating gates are arranged in a row direction and in a column direction and each of the first isolation structures extends in the column direction, further comprising:
a plurality of word lines, each disposed over a row of floating gates; and
an inter-gate dielectric layer, disposed between each floating gate and the word line over the floating gate.

9. The structure of claim 8, further comprising a plurality of second isolation structures lower than the first isolation structures in height and extending in the column direction, wherein
the first isolation structures and the second isolation structures are arranged alternately in the row direction,
each second isolation structure is located between two columns of floating gates respectively on two opposite sidewalls of two neighboring first isolation structures, and
a width of each of the first and second isolation structures is equal to or smaller than double of a thickness of the inter-gate dielectric layer above the floating gates.

10. The structure of claim 8, further comprising:
a row of select gates as second conductive spacers on the sidewalls of the first isolation structures protrudent over the substrate; and
a select line, disposed over and contacting the row of select gates.

11. A process for fabricating a non-volatile memory, comprising:
forming a plurality of first isolation structures disposed in and protrudent over a substrate;
forming a tunneling layer over the substrate; and
forming a plurality of floating gates as first conductive spacers on sidewalls of the first isolation structures protrudent over the substrate.

12. The process of claim 11, further comprising: forming a plurality of second isolation structures lower than the first isolation structures in height during the step of forming the first isolation structures, wherein
the floating gates are arranged in a row direction and in a column direction,
each of the first and second isolation structures extends in the column direction,
the first isolation structures and the second isolation structures are arranged alternately in the row direction, and
each second isolation structure is located between two columns of floating gates respectively on two opposite sidewalls of two neighboring first isolation structures.

13. The method of claim 12, wherein the step of forming the first and the second isolation structures comprises:
forming a plurality of trenches in the substrate using a patterned mask layer as an etching mask, wherein the mask layer has therein gaps corresponding to the trenches;
filling the trenches and the gaps with a plurality of insulating layers;
recessing a part of the insulating layers in a manner such that recessed insulating layers and non-recessed insulating layers are arranged alternately; and
removing the mask layer so that the non-recessed insulating layers form the first isolation structures and the recessed insulating layers form the second isolation structures.

14. The process of claim 11, further comprising:
forming a row of select gates as second conductive spacers on the sidewalls of the first isolation structures during the step of forming the floating gates.

15. The process of claim 11, wherein the non-volatile memory has a critical dimension smaller than 30 nm.

16. The process of claim 11, wherein forming the floating gates comprises:
forming a plurality of conductive spacer bars on the sidewalls of the first isolation structures protrudent over the substrate; and
patterning the conductive spacer bars.

17. The process of claim 16, wherein the floating gates are arranged in a row direction and in a column direction and each of the first isolation structures extends in the column direction, further comprising:
forming an inter-gate dielectric layer over the substrate after the conductive spacer bars are formed but before the conductive spacer bars are patterned; and
forming a plurality of word lines extending in the row direction over the inter-gate dielectric layer,
wherein the conductive spacer bars are patterned following the word lines so that each word line is disposed over a row of floating gates.

18. The process of claim 17, further comprising: forming a plurality of second isolation structures lower than the first isolation structures in height and extending in the column direction during the step of forming the first isolation structures, wherein
the first isolation structures and the second isolation structures are arranged alternately in the row direction,
each second isolation structure is located between two columns of floating gates respectively on two opposite sidewalls of two neighboring first isolation structures, and
a width of each of the first and second isolation structures is equal to or smaller than double of a thickness of the inter-gate dielectric layer above the floating gates.

19. The process of claim 17, further comprising:
during the step of patterning the conductive spacer bars, forming a row of select gates as second conductive spacers on the sidewalls of the first isolation structures protrudent over the substrate;
after the step of forming the inter-gate dielectric layer but before the step of forming the word lines, removing a portion of the inter-gate dielectric layer over portions of the conductive spacer bars predetermined to form the row of select gates such that at least a part of each of the portions of the conductive spacer bars is exposed; and
during the step of forming the word lines, forming a select line disposed over and contacting the portions of the conductive spacer bars,
wherein the conductive spacer bars are patterned also following the select line, so that the row of select gates are formed together with the floating gates.
